(19) United States
(12) Patent Application Publication
(10) Pub. No.: US 2022/0255144 A1
(43) Pub. Date: Aug. 11, 2022

(54) BATTERY INFORMATION MANAGEMENT SYSTEM, NODE, MANAGEMENT METHOD, RECORDING METHOD, AND COMPUTER PROGRAM

(71) Applicant: SUMITOMO ELECTRIC INDUSTRIES, LTD., Osaka-shi, Osaka (JP)

(72) Inventors: Shinichi OKANO, Osaka-shi (JP); Koji ARAI, Osaka-shi (JP); Aoi HATANAKA, Osaka-shi (JP); Tomomi KATAOKA, Osaka-shi (JP); Hiroaki TAKECHI, Osaka-shi (JP); Takahiro MATSUURA, Osaka-shi (JP)

(73) Assignee: SUMITOMO ELECTRIC INDUSTRIES, LTD., Osaka-shi, Osaka (JP)

(21) Appl. No.: 17/627,582

(22) PCT Filed: Jun. 22, 2020
(86) PCT No.: PCT/JP2020/024331

§ 371 Date: Jan. 14, 2022

(30) Foreign Application Priority Data
Jul. 18, 2019 (JP) 2019-133147

(51) Int. Cl. H01M 10/42

(52) U.S. Cl. CPC H01M 10/425; B60L 58/16; H01M 2010/4271; H01M 2220/20

(57) ABSTRACT

A battery information management system includes: a battery characteristic calculation unit calculating a battery characteristic for each of a plurality of unit cells; a transmission unit transmitting value information that includes the battery characteristic of each unit cell, unit cell identification information, and time information; and a distributed-type database network recording the value information of each unit cell. A specific node of the distributed-type database network includes a reception unit configured to receive the value information transmitted from the transmission unit, and a transaction delivery unit configured to deliver, to the plurality of nodes, a transaction of recording the value information. Each of the plurality of nodes includes a verification processing unit configured to perform verification on the value information, an approval processing unit configured to approve the value information, and a recording processing unit configured to record the value information, into the storage medium.

### TECHNICAL FIELD

The present disclosure relates to a battery information management system, a node, a management method, a recording method, and a computer program. This application claims priority on Japanese Patent Application No. 2019-133147 filed on Jul. 18, 2019, the entire content of which is incorporated herein by reference.

### BACKGROUND ART

Vehicles such as hybrid electric vehicles (HEVs) and electric vehicles (EVs) are becoming prevalent. HEVs and EVs are equipped with secondary batteries. A secondary battery mounted on a vehicle is a battery pack obtained by combining a plurality of secondary battery modules which are each obtained by combining a plurality of battery cells. The battery cell and the secondary battery module each have battery characteristics individually. One battery pack is produced by combining battery cells and secondary battery modules having similar or equivalent battery characteristics. However, when charging/discharging has been repeated due to use, variation occurs in the battery characteristics. A method for reconfiguring a battery pack by selecting reusable secondary battery modules out of a used battery pack has been proposed.

PATENT LITERATURE 1 discloses a method in which: all of battery characteristics such as full charge capacity, state of health, and the like are measured for each secondary battery module or each battery cell included in a battery pack; and whether or not the secondary battery module or the battery cell is reusable is determined.

NON PATENT LITERATURE 1 indicates that: battery packs are collected; and performances (full charge capacity, state of health) of all secondary battery modules of the collected battery packs are measured and classified for reuse thereof. The collected secondary battery modules are classified into: those to be reused in drive of an HEV or an EV; those to be reused in an industrial vehicle such as a forklift; and those to be reused in a backup power supply or the like.

### CITATION LIST

### Patent Literature

PATENT LITERATURE 1: Japanese Laid-Open Patent Publication No. 2016-152110

PATENT LITERATURE 2: Japanese Laid-Open Patent Publication No. 2018-013456

PATENT LITERATURE 3: Japanese Laid-Open Patent Publication No. 2017-203659

PATENT LITERATURE 4: Japanese Laid-Open Patent Publication No. 2017-194284

PATENT LITERATURE 5: Japanese Laid-Open Patent Publication No. 2017-194283

### Non Patent Literature

NON PATENT LITERATURE 1: “4R Energy ‘LEAF’ no juudenchi wo saiseihinkasuru Namie Jigyousho no jigyou nituite setsumei (provisional translation: 4R Energy describes business of Namie manufacturing plant for remanufacturing secondary batteries of ‘LEAF’) [online], Impress Corporation, Car Watch [searched on Apr. 11, 2018], the Internet (URL: https://car.watch.impress.co.jp/docs/news/1113869.html)

### SUMMARY OF INVENTION

A battery information management system according to one mode of the present disclosure is configured to manage a reuse value of a secondary battery that includes a plurality of unit cells. The battery information management system includes: a battery characteristic calculation unit configured to calculate a battery characteristic for each of the plurality of unit cells; a transmission unit configured to transmit value information that includes the battery characteristic, of each unit cell, calculated by the battery characteristic calculation unit, unit cell identification information identifying the unit cell, and time information indicating a time at which the battery characteristic has been calculated; and a distributed-type database network configured to record the value information, of each unit cell, transmitted by the transmission unit. The distributed-type database network includes a plurality of nodes each having a storage medium. A specific node of the plurality of nodes is a computer configured to manage the battery characteristic of the unit cell, and includes a reception unit configured to receive the value information transmitted from the transmission unit, and a transaction delivery unit configured to deliver, to the plurality of nodes, a transaction of recording the value information received by the reception unit. Each of the plurality of nodes includes a verification processing unit configured to perform verification on the value information relating to the transaction, an approval processing unit configured to approve the value information that has been verified, and a recording processing unit configured to record the value information that has been approved, into the storage medium.

A node according to one mode of the present disclosure is a specific node being a computer configured to manage a battery characteristic of each of a plurality of unit cells forming a secondary battery. The specific node includes:

a reception unit configured to receive value information that includes the battery characteristic of each unit cell, unit cell identification information identifying the unit cell, and time information indicating a time at which the battery characteristic has been calculated; an authentication unit configured to perform authentication on a transmission source of the value information; and a transaction delivery unit configured to deliver, on the basis of an authentication result of the authentication unit, a transaction for recording the value information, to a plurality of nodes included in a distributed-type database network. Each of the plurality of nodes includes a storage medium into which the value information of the unit cell is recorded.

A node according to another mode of the present disclosure is a node forming a distributed-type database network including a plurality of nodes each having a storage medium. The node includes: a verification processing unit configured to perform verification on value information relating to a transaction that has been delivered from a specific node and that is for recording the value information into the distributed-type database network; an approval processing unit configured to approve the value information that has been verified; and a recording processing unit configured to record the value information that has been approved, into the storage medium. The value information includes a battery characteristic of each of a plurality of unit cells forming a secondary battery, unit cell identification information identifying each unit cell, and time information indicating a time at which the battery characteristic has been calculated.

A management method according to one mode of the present disclosure is a management method for a battery characteristic of each of a plurality of unit cells forming a secondary battery, and is to be performed by a computer configured to manage the battery characteristic. The management method includes the steps of: receiving value information that includes the battery characteristic of each unit cell, unit cell identification information identifying the unit cell, and time information indicating a time at which the battery characteristic has been calculated; performing authentication on a transmission source of the value information; and delivering, on the basis of an authentication result regarding the transmission source, a transaction for recording the value information, to a plurality of nodes included in a distributed-type database network. Each of the plurality of nodes includes a storage medium into which the value information of the unit cell is recorded.

A recording method according to one mode of the present disclosure is a recording method, of value information, performed by a node forming a distributed-type database network that includes a plurality of nodes each having a storage medium. The recording method includes the steps of: performing verification on value information relating to a transaction that has been delivered from a specific node and that is for recording the value information into the distributed-type database network; approving the value information that has been verified; and recording the value information that has been approved, into the storage medium. The value information includes a battery characteristic of each of a plurality of unit cells forming a secondary battery, unit cell identification information identifying each unit cell, and time information indicating a time at which the battery characteristic has been calculated.

A computer program according to one mode of the present disclosure is for causing a computer to function as a specific node configured to manage a battery characteristic of each of a plurality of unit cells forming a secondary battery. The computer program causes the computer to function as: a reception unit configured to receive value information that includes the battery characteristic of each unit cell, unit cell identification information identifying the unit cell, and time information indicating a time at which the battery characteristic has been calculated; an authentication unit configured to perform authentication on a transmission source of the value information; and a transaction delivery unit configured to deliver, on the basis of an authentication result of the authentication unit, a transaction for recording the value information, to a plurality of nodes included in a distributed-type database network. Each of the plurality of nodes includes a storage medium into which the value information of the unit cell is recorded.

A computer program according to another mode of the present disclosure is for causing a computer to function as a node forming a distributed-type database network that includes a plurality of nodes each having a storage medium. The computer program causes the computer to function as: a verification processing unit configured to perform verification on value information relating to a transaction that has been delivered from a specific node and that is for recording the value information into the distributed-type database network; an approval processing unit configured to approve the value information that has been verified; and a recording processing unit configured to record the value information that has been approved, into the storage medium. The value information includes a battery characteristic of each of a plurality of unit cells forming a secondary battery, unit cell identification information identifying each unit cell, and time information indicating a time at which the battery characteristic has been calculated.

The present disclosure can be realized not only as a battery information processing system that includes such characteristic configurations described above, but also as a battery information processing method that has such characteristic processes as steps, or as a program for causing a computer to execute such steps. Further, the present disclosure can be realized as a node (computer) forming a battery information processing system, can be realized as a method that has as steps such characteristic processes executed by a node, or can be realized as a program for causing a computer to execute such steps. The present disclosure can be realized as a semiconductor integrated circuit that realizes a part or the entirety of the battery information processing system, or can be realized as another system that includes the battery information processing system.

### BRIEF DESCRIPTION OF DRAWINGS

FIG. 1 shows an outline of a battery information processing system.

FIG. 2 is a block diagram showing a configuration of a plurality of battery module devices and the like mounted on a vehicle.

FIG. 3 is a block diagram showing a configuration example of a battery management unit.

FIG. 4 is a function block diagram of a module control unit in the embodiment.

FIG. 5A illustrates an example of an equivalent circuit model of a battery cell.

FIG. 5B illustrates another example of an equivalent circuit model of the battery cell.

FIG. 5C illustrates still another example of an equivalent circuit model of the battery cell.

FIG. 6 is a conceptual diagram showing value information that is recorded in a distributed-type database network.

FIG. 7 is a block diagram showing a configuration example of a node.

FIG. 8 is a block diagram showing a configuration example of an authority management node.

FIG. 9 is a flow chart showing a process procedure of recording value information and detailed information.

FIG. 10 is a conceptual diagram of a block chain.

FIG. 11 is a flow chart of a process procedure of changing a manager.

FIG. 12 is a flow chart showing a process procedure of viewing value information and detailed information.

FIG. 13 is a conceptual diagram for describing effects of the battery information management system according to the embodiment.

### DESCRIPTION OF EMBODIMENTS

### Problems to be Solved by the Present Disclosure

In the cases of the reuse of secondary batteries disclosed in PATENT LITERATURE 1 and NON PATENT LITERATURE 1, measurement is performed at the time of disassembly of a battery pack, and the deterioration state, i.e., battery characteristics, is evaluated. In NON PATENT LITERATURE 1, performing inspection of 48 secondary battery modules requires four hours in total. Secondary battery modules or battery cells that have truly uniform battery characteristics are difficult to be combined, on the basis of battery characteristics that are obtained through temporary measurement performed at the time point of disassembly.

### Effects of the Present Disclosure

According to the present disclosure, during use of the apparatus on which a secondary battery is mounted, battery characteristics of the secondary battery can be recorded per unit cell in such a manner as not to be falsified, whereby battery characteristics can be read out when necessary.

### Outline of Embodiments of the Present Disclosure

First, contents of an embodiment of the present disclosure are listed and described.

(1) A battery information management system according to the present embodiment is configured to manage a reuse value of a secondary battery that includes a plurality of unit cells. The battery information management system includes: a battery characteristic calculation unit configured to calculate a battery characteristic for each of the plurality of unit cells; a transmission unit configured to transmit value information that includes the battery characteristic, of each unit cell, calculated by the battery characteristic calculation unit, unit cell identification information identifying the unit cell, and time information indicating a time at which the battery characteristic has been calculated; and a distributed-type database network configured to record the value information, of each unit cell, transmitted by the transmission unit. The distributed-type database network includes a plurality of nodes each having a storage medium. A specific node of the plurality of nodes is a computer configured to manage the battery characteristic of the unit cell, and includes a reception unit configured to receive the value information transmitted from the transmission unit, and a transaction delivery unit configured to deliver, to the plurality of nodes, a transaction of recording the value information received by the reception unit. Each of the plurality of nodes includes a verification processing unit configured to perform verification on the value information relating to the transaction, an approval processing unit configured to approve the value information that has been verified, and a recording processing unit configured to record the value information that has been approved, into the storage medium.

In the present mode, battery characteristics of a plurality of unit cells forming a secondary battery mounted on an arbitrary apparatus are calculated for each unit cell. The unit cell here means a unit of a battery for which calculation or management of battery characteristics is performed. Calculation of battery characteristics is performed at an appropriate timing during use of the apparatus. Value information that includes the calculated battery characteristics, unit cell identification information, and time information is transmitted to a computer that manages the battery characteristics of unit cells. The computer is a specific node forming a distributed-type database network. The specific node delivers, to the distributed-type database network, a transaction of recording the value information of each unit cell, and the value information is verified and approved, and is recorded into the distributed-type database network in such a manner as not to be falsified. That is, history of battery characteristics of the plurality of unit cells mounted on the apparatus is recorded into the distributed-type database network in such a manner as not to be falsified.

When a secondary battery or a unit cell is to be reused, it is necessary to know characteristics of each unit cell. In general, identification of battery characteristics of a unit cell takes several hours of measurement. However, according to the present mode, by reading out battery characteristics of each unit cell recorded in the distributed-type database network, it is possible to immediately confirm the battery characteristics of the unit cell.

Therefore, when a secondary battery or a unit cell is to be reused, various types of measurement work having conventionally been performed are not required. Thus, the operator can efficiently understand the deterioration state of the unit cell, and can efficiently distinguish a unit cell in a good state from a unit cell in a bad state.

The value information of each unit cell is recorded into the distributed-type database network through a transaction delivered by a specific node of a manager of the secondary battery. The value information that the specific node is to record into the distributed-type database network is verified on the basis of an electronic signature obtained from secret key information corresponding to the specific node, then is approved, and thereafter, is recorded into the distributed-type database network. In other words, the value information of the unit cell is recorded by the manager of the secondary battery into the distributed-type database network referred to as a so-called block chain in such a manner as not to be falsified. Traceability of the unit cell with respect to the value information can be improved.

Therefore, it is possible to improve the value, as a reuse resource, of a secondary battery or a unit cell for which authenticity of history information regarding battery characteristics is ensured, and accordingly, it is possible to improve the value of the apparatus on which the secondary battery is mounted.

(2) The distributed-type database network may be configured to record manager information indicating a manager of the unit cell and information regarding change of the manager.

In the present mode, the manager information is recorded into the distributed-type database network together with the value information of the unit cell. When the ownership of the secondary battery has been transferred and the manager of the secondary battery has been changed, information regarding the change of the manager is recorded into the distributed-type database network. Accordingly, information of the manager who collects and records the value information of the unit cell, and the information of change of the manager are also recorded into the distributed-type database network in such a manner as not to be falsified. Therefore, traceability of the unit cell with respect to the value information can be improved.

(3) When the transaction of recording the value information of the unit cell has been delivered from the specific node that corresponds to the manager of the unit cell, the distributed-type database network may record the value information, and when the transaction has been delivered from a node that does not correspond to the manager, the distributed-type database network may reject recording of the value information.

In the present mode, the transaction of recording the value information is recorded into the distributed-type database network only when the transaction has been delivered from a specific node that corresponds to the manager of the unit cell. The transaction that has been delivered from a node other than that of the manager of the unit cell is not recorded into the distributed-type database network even when the transaction itself is authentic. Therefore, authenticity of the value information can be improved. Accordingly, traceability of the unit cell with respect to the value information can be improved.

(4) The distributed-type database network may provide viewing authority of the value information to a user of the distributed-type database network, and may manage a range of the value information that is allowed to be viewed by the user.

In the present mode, the range of the value information, of the unit cell, that can be viewed can be restricted in accordance with the viewing authority of the user.

(5) The transmission unit may be configured to transmit detailed information serving as a calculation source of the battery characteristic, and the reception unit may be configured to receive the detailed information transmitted from the transmission unit. The specific node may include a recording device outside the distributed-type database network, and may record, into the recording device, the detailed information received by the reception unit.

In the present mode, the specific node can record, into the recording device, detailed information serving as a calculation source of the value information of the unit cell. The detailed information is data having a large volume when compared with the value information, and thus, the distributed-type database network is not appropriate as a recording destination. Therefore, in the battery information management unit according to the present mode, the detailed information is recorded into a recording device that is different from the distributed-type database network, whereas the value information is recorded into the distributed-type database network.

Since both of the value information and the detailed information of the unit cell are recorded, reliability of the value information can be more improved. Therefore, traceability of the unit cell with respect to the value information can be further improved.

(6) The transmission unit may be configured to transmit detailed information serving as a calculation source of the battery characteristic, and the reception unit may be configured to receive the detailed information transmitted from the transmission unit. The specific node may include a recording device outside the distributed-type database network, and may record, into the recording device, the detailed information received by the reception unit, and when having received a request from a user having viewing authority of the value information recorded in the distributed-type database network, may transmit the detailed information recorded in the recording device, to a source of the request.

In the present mode, similar to mode (5), since both of the value information and the detailed information of the unit cell are recorded, reliability of the value information can be more improved.

The user who can read out value information of a unit cell from the distributed-type database network can request, to a specific node, detailed information that corresponds to the value information, and acquire the detailed information. The user can confirm in more detail the state of the unit cell on the basis of the value information and the detailed information.

(7) When a manager of the unit cell has been changed, the specific node serving as a transmission destination of the value information may be changed.

In the present mode, in association with change of the manager of the secondary battery, the node serving as the transmission destination of the value information can be changed. Specifically, the value information is transmitted to a node that manages the state of the secondary battery and that executes the process of recording the value information, whereby the battery characteristics of the unit cell can be efficiently recorded without errors.

(8) A node according to the present embodiment is a specific node being a computer configured to manage a battery characteristic of each of a plurality of unit cells forming a secondary battery. The specific node includes: a reception unit configured to receive value information that includes the battery characteristic of each unit cell, unit cell identification information identifying the unit cell, and time information indicating a time at which the battery characteristic has been calculated; an authentication unit configured to perform authentication on a transmission source of the value information; and a transaction delivery unit configured to deliver, on the basis of an authentication result of the authentication unit, a transaction for recording the value information, to a plurality of nodes included in a distributed-type database network. Each of the plurality of nodes includes a storage medium into which the value information of the unit cell is recorded.

When a secondary battery or a unit cell is to be reused, it is necessary to know characteristics of each unit cell. In general, identification of battery characteristics of a unit cell takes several hours of measurement. However, according to the present mode, by reading out battery characteristics of each unit cell recorded in the distributed-type database network, it is possible to immediately confirm the battery characteristics of the unit cell.

Therefore, when a secondary battery or a unit cell is to be reused, various types of measurement work having conventionally been performed are not required. Thus, the operator can efficiently understand the deterioration state of the unit cell, and can efficiently distinguish a unit cell in a good state from a unit cell in a bad state.

The value information of each unit cell is recorded into the distributed-type database network through a transaction delivered by a specific node of a manager of the secondary battery. The value information that the specific node is to record into the distributed-type database network is verified on the basis of an electronic signature obtained from secret key information corresponding to the specific node, then is approved, and thereafter, is recorded into the distributed-type database network. In other words, the value information of the unit cell is recorded by the manager of the secondary battery into the distributed-type database network referred to as a so-called block chain in such a manner as not to be falsified. Traceability of the unit cell with respect to the value information can be improved.

Therefore, it is possible to improve the value, as a reuse resource, of a secondary battery or a unit cell for which authenticity of history information regarding battery characteristics is ensured, and accordingly, it is possible to improve the value of the apparatus on which the secondary battery is mounted.

(9) A node according to the present embodiment is a node forming a distributed-type database network including a plurality of nodes each having a storage medium. The node includes: a verification processing unit configured to perform verification on value information relating to a transaction that has been delivered from a specific node and that is for recording the value information into the distributed-type database network; an approval processing unit configured to approve the value information that has been verified; and a recording processing unit configured to record the value information that has been approved, into the storage medium. The value information includes a battery characteristic of each of a plurality of unit cells forming a secondary battery, unit cell identification information identifying each unit cell, and time information indicating a time at which the battery characteristic has been calculated.

When a secondary battery or a unit cell is to be reused, it is necessary to know characteristics of each unit cell. In general, identification of battery characteristics of a unit cell takes several hours of measurement. However, according to the present mode, by reading out battery characteristics of each unit cell recorded in the distributed-type database network, it is possible to immediately confirm the battery characteristics of the unit cell.

Therefore, when a secondary battery or a unit cell is to be reused, various types of measurement work having conventionally been performed are not required. Thus, the operator can efficiently understand the deterioration state of the unit cell, and can efficiently distinguish a unit cell in a good state from a unit cell in a bad state.

The value information of each unit cell is recorded into the distributed-type database network through a transaction delivered by a specific node of a manager of the secondary battery. The value information that the specific node is to record into the distributed-type database network is verified on the basis of an electronic signature obtained from secret key information corresponding to the specific node, then is approved, and thereafter, is recorded into the distributed-type database network. In other words, the value information of the unit cell is recorded by the manager of the secondary battery into the distributed-type database network referred to as a so-called block chain in such a manner as not to be falsified. Traceability of the unit cell with respect to the value information can be improved.

Therefore, it is possible to improve the value, as a reuse resource, of a secondary battery or a unit cell for which authenticity of history information regarding battery characteristics is ensured, and accordingly, it is possible to improve the value of the apparatus on which the secondary battery is mounted.

(10) A management method according to the present embodiment is a management method for a battery characteristic of each of a plurality of unit cells forming a secondary battery, the management method being configured to be performed by a computer configured to manage the battery characteristic. The management method includes the steps of: receiving value information that includes the battery characteristic of each unit cell, unit cell identification information identifying the unit cell, and time information indicating a time at which the battery characteristic has been calculated; performing authentication on a transmission source of the value information; and delivering, on the basis of an authentication result regarding the transmission source, a transaction for recording the value information, to a plurality of nodes included in a distributed-type database network. Each of the plurality of nodes includes a storage medium into which the value information of the unit cell is recorded.

When a secondary battery or a unit cell is to be reused, it is necessary to know characteristics of each unit cell. In general, identification of battery characteristics of a unit cell takes several hours of measurement. However, according to the present mode, by reading out battery characteristics of each unit cell recorded in the distributed-type database network, it is possible to immediately confirm the battery characteristics of the unit cell.

Therefore, when a secondary battery or a unit cell is to be reused, various types of measurement work having conventionally been performed are not required. Thus, the operator can efficiently understand the deterioration state of the unit cell, and can efficiently distinguish a unit cell in a good state from a unit cell in a bad state.

The value information of each unit cell is recorded into the distributed-type database network through a transaction delivered by a specific node (computer) of a manager of the secondary battery. The value information that the specific node is to record into the distributed-type database network is verified on the basis of an electronic signature obtained from secret key information corresponding to the specific node, then is approved, and thereafter, is recorded into the distributed-type database network. In other words, the value information of the unit cell is recorded by the manager of the secondary battery into the distributed-type database network referred to as a so-called block chain in such a manner as not to be falsified. Traceability of the unit cell with respect to the value information can be improved.

Therefore, it is possible to improve the value, as a reuse resource, of a secondary battery or a unit cell for which authenticity of history information regarding battery characteristics is ensured, and accordingly, it is possible to improve the value of the apparatus on which the secondary battery is mounted.

(11) A recording method according to the present embodiment is a recording method, of value information, performed by a node forming a distributed-type database network that includes a plurality of nodes each having a storage medium. The recording method includes the steps of: performing verification on value information relating to a transaction that has been delivered from a specific node and that is for recording the value information into the distributed-type database network; approving the value information that has been verified; and recording the value information that has been approved, into the storage medium. The value information includes a battery characteristic of each of a plurality of unit cells forming a secondary battery, unit cell identification information identifying each unit cell, and time information indicating a time at which the battery characteristic has been calculated.

When a secondary battery or a unit cell is to be reused, it is necessary to know characteristics of each unit cell. In general, identification of battery characteristics of a unit cell takes several hours of measurement. However, according to the present mode, by reading out battery characteristics of each unit cell recorded in the distributed-type database network, it is possible to immediately confirm the battery characteristics of the unit cell.

Therefore, when a secondary battery or a unit cell is to be reused, various types of measurement work having conventionally been performed are not required. Thus, the operator can efficiently understand the deterioration state of the unit cell, and can efficiently distinguish a unit cell in a good state from a unit cell in a bad state.

The value information of each unit cell is recorded into the distributed-type database network through a transaction delivered by a specific node of a manager of the secondary battery. The value information that the specific node is to record into the distributed-type database network is verified on the basis of an electronic signature obtained from secret key information corresponding to the specific node, then is approved, and thereafter, is recorded into the distributed-type database network. In other words, the value information of the unit cell is recorded by the manager of the secondary battery into the distributed-type database network referred to as a so-called block chain in such a manner as not to be falsified. Traceability of the unit cell with respect to the value information can be improved.

Therefore, it is possible to improve the value, as a reuse resource, of a secondary battery or a unit cell for which authenticity of history information regarding battery characteristics is ensured, and accordingly, it is possible to improve the value of the apparatus on which the secondary battery is mounted.

(12) A computer program according to the present embodiment is for causing a computer to function as a specific node configured to manage a battery characteristic of each of a plurality of unit cells forming a secondary battery. The computer program causes the computer to function as: a reception unit configured to receive value information that includes the battery characteristic of each unit cell, unit cell identification information identifying the unit cell, and time information indicating a time at which the battery characteristic has been calculated; an authentication unit configured to perform authentication on a transmission source of the value information; and a transaction delivery unit configured to deliver, on the basis of an authentication result of the authentication unit, a transaction for recording the value information, to a plurality of nodes included in a distributed-type database network. Each of the plurality of nodes includes a storage medium into which the value information of the unit cell is recorded.

When a secondary battery or a unit cell is to be reused, it is necessary to know characteristics of each unit cell. In general, identification of battery characteristics of a unit cell takes several hours of measurement. However, according to the present mode, by reading out battery characteristics of each unit cell recorded in the distributed-type database network, it is possible to immediately confirm the battery characteristics of the unit cell.

Therefore, when a secondary battery or a unit cell is to be reused, various types of measurement work having conventionally been performed are not required. Thus, the operator can efficiently understand the deterioration state of the unit cell, and can efficiently distinguish a unit cell in a good state from a unit cell in a bad state.

The value information of each unit cell is recorded into the distributed-type database network through a transaction delivered by a specific node of a manager of the secondary battery. The value information that the specific node is to record into the distributed-type database network is verified on the basis of an electronic signature obtained from secret key information corresponding to the specific node, then is approved, and thereafter, is recorded into the distributed-type database network. In other words, the value information of the unit cell is recorded by the manager of the secondary battery into the distributed-type database network referred to as a so-called block chain in such a manner as not to be falsified. Traceability of the unit cell with respect to the value information can be improved.

Therefore, it is possible to improve the value, as a reuse resource, of a secondary battery or a unit cell for which authenticity of history information regarding battery characteristics is ensured, and accordingly, it is possible to improve the value of the apparatus on which the secondary battery is mounted.

(13) A computer program according to the present embodiment is for causing a computer to function as a node forming a distributed-type database network that includes a plurality of nodes each having a storage medium. The computer program causes the computer to function as: a verification processing unit configured to perform verification on value information relating to a transaction that has been delivered from a specific node and that is for recording the value information into the distributed-type database network; an approval processing unit configured to approve the value information that has been verified; and a recording processing unit configured to record the value information that has been approved, into the storage medium. The value information includes a battery characteristic of each of a plurality of unit cells forming a secondary battery, unit cell identification information identifying each unit cell, and time information indicating a time at which the battery characteristic has been calculated.

When a secondary battery or a unit cell is to be reused, it is necessary to know characteristics of each unit cell. In general, identification of battery characteristics of a unit cell takes several hours of measurement. However, according to the present mode, by reading out battery characteristics of each unit cell recorded in the distributed-type database network, it is possible to immediately confirm the battery characteristics of the unit cell.

Therefore, when a secondary battery or a unit cell is to be reused, various types of measurement work having conventionally been performed are not required. Thus, the operator can efficiently understand the deterioration state of the unit cell, and can efficiently distinguish a unit cell in a good state from a unit cell in a bad state.

The value information of each unit cell is recorded into the distributed-type database network through a transaction delivered by a specific node of a manager of the secondary battery. The value information that the specific node is to record into the distributed-type database network is verified on the basis of an electronic signature obtained from secret key information corresponding to the specific node, then is approved, and thereafter, is recorded into the distributed-type database network. In other words, the value information of the unit cell is recorded by the manager of the secondary battery into the distributed-type database network referred to as a so-called block chain in such a manner as not to be falsified. Traceability of the unit cell with respect to the value information can be improved.

Therefore, it is possible to improve the value, as a reuse resource, of a secondary battery or a unit cell for which authenticity of history information regarding battery characteristics is ensured, and accordingly, it is possible to improve the value of the apparatus on which the secondary battery is mounted.

### Details of Embodiments of the Present Disclosure

Hereinafter, specific examples of a battery information management system according to an embodiment of the present disclosure will be described with reference to the drawings. The present disclosure is not limited to these examples, and is defined by the scope of the claims and intended to include meaning equivalent to the scope of the claims and all modifications within the scope. At least some parts of the embodiment described below may be combined as desired.

Hereinafter, an embodiment of the present disclosure will be specifically described with reference to the drawings.

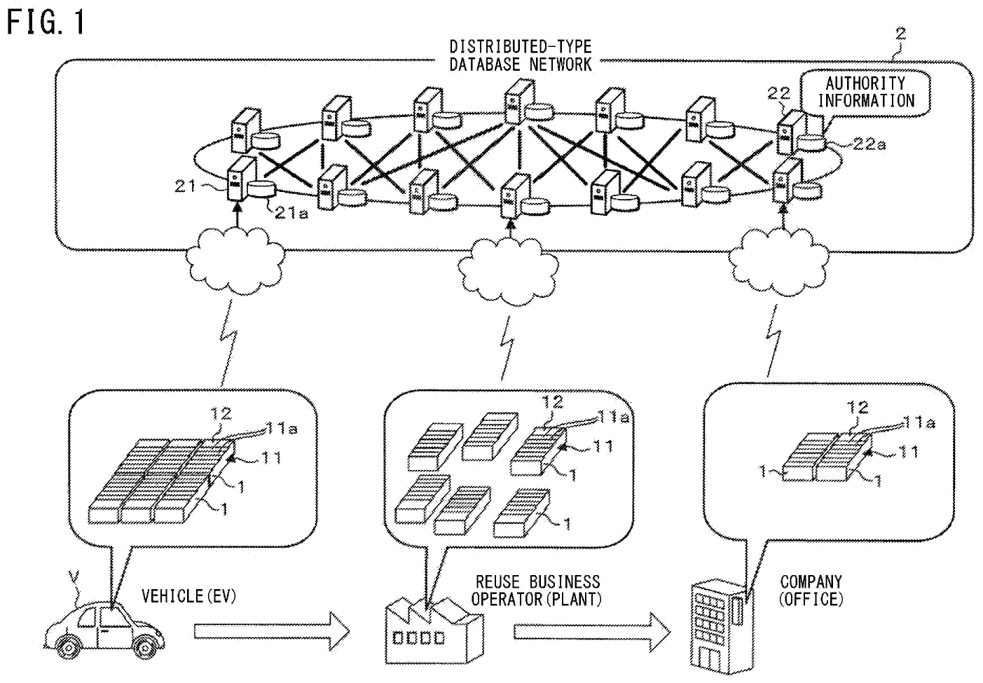

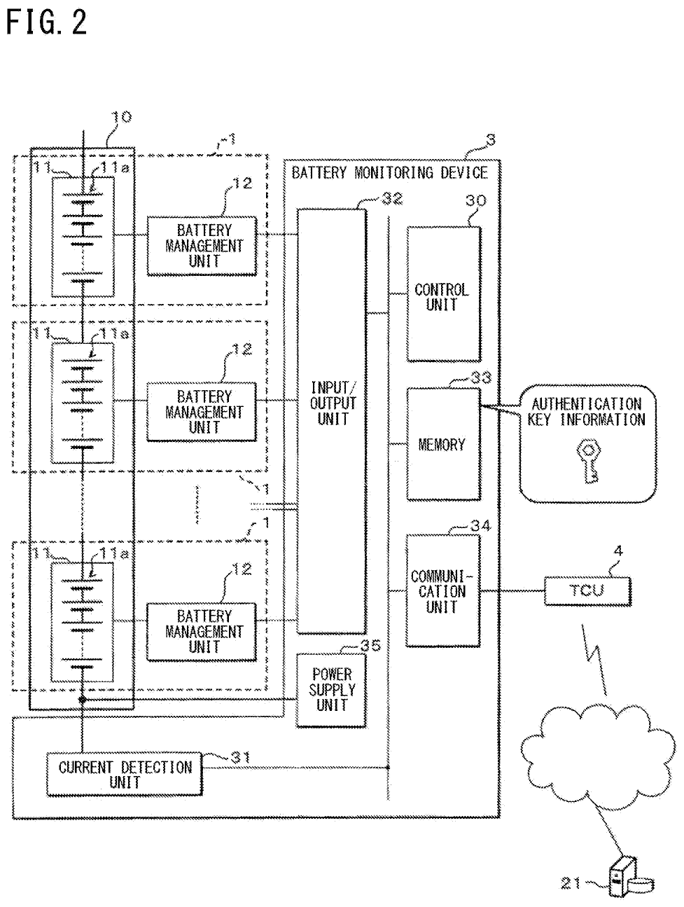

FIG. 1 shows an outline of a battery information management system. The battery information management system is a system that supports reuse of a secondary battery 10 (see FIG. 2) or a secondary battery module 11, e.g., reuse of a secondary battery 10 used in a vehicle V such as an EV or an HEV.

For example, as shown in FIG. 1, a used secondary battery 10 having been mounted on a vehicle V is disassembled into secondary battery modules 11 at a plant of a reuse business operator, and is selected and resold in accordance with the deterioration state thereof. At an office of a company, a secondary battery module 11 is reused for non-vehicle use.

In order to efficiently reuse a secondary battery 10 or a secondary battery module 11, it is necessary to understand battery characteristics of a used secondary battery 10 or a used secondary battery module 11. The battery information management system according to the present embodiment is a system that realizes traceability of a secondary battery 10 by recording battery characteristics of the secondary battery 10 per module or per unit cell in such a manner as not to be falsified.

The battery information processing system includes a plurality of battery module devices 1 and a distributed-type database network 2. Hereinafter, a state where the battery module devices 1 are mounted on a vehicle V is described as an example.

Each battery module device 1 includes a secondary battery module 11 and a battery management unit (BMU) 12. The secondary battery module 11 is formed by connecting a plurality of battery cells 11a in series or in series-parallel. Each battery cell 11a is a lithium ion battery, for example. A secondary battery 10 is formed by a plurality of secondary battery modules 11.

The battery cell 11a and the secondary battery module 11 according to the embodiment correspond to a unit cell and a secondary battery according to mode (1) above, and the secondary battery module 11 and the secondary battery 10 according to the present embodiment are also a unit cell and a secondary battery according to mode (1) above. The battery cell 11a and the secondary battery 10 according to the present embodiment may be considered as a unit cell and a secondary battery according to mode (1) above. In the present mode, the “unit cell” means a unit of a battery for which calculation and management of battery characteristics are performed, and the “secondary battery” means a battery pack composed of a plurality of unit cells.

The distributed-type database network 2 includes: a plurality of nodes 21 each having a storage medium 21a; and an authority management node 22. Each node 21 and the authority management node 22 are connected in a P2P (Peer to Peer) manner. The distributed-type database network 2 forms a so-called block chain. The distributed-type database network 2 of the present embodiment is a consortium-type block chain that can manage information-writing-authority of a node 21 and viewing authority of a user, for example. Details of each node 21 and the authority management node 22 will be described later.

FIG. 2 is a block diagram showing a configuration of a plurality of battery module devices 1 and the like mounted on a vehicle V. The vehicle V has mounted thereon a plurality of battery module devices 1, a battery monitoring device 3, and a TCU (Telematics Communication Unit) 4. A power supply system using the secondary battery 10 in the vehicle V includes a relay, a generator (ALT), a starter motor, a battery, an electric load, a starting switch, a charger, and the like, in addition to the battery module devices 1. Detailed description of the power supply system is omitted.

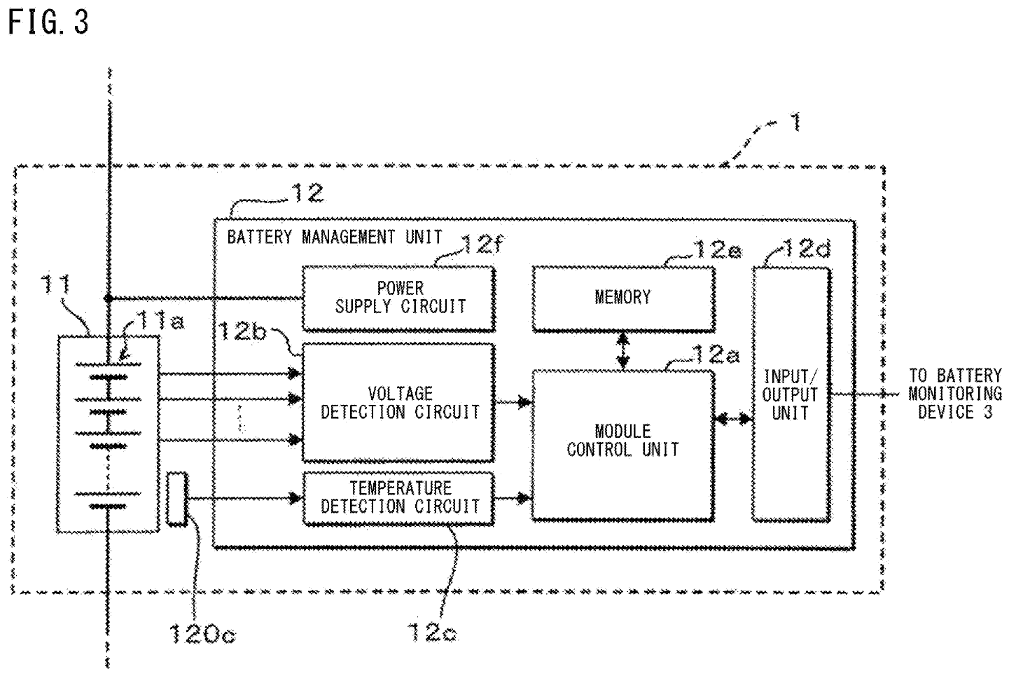

FIG. 3 is a block diagram showing a configuration example of a battery management unit 12. The battery management unit 12 is provided to each of the plurality of secondary battery modules 11. Since the battery management units 12 have the same configuration, one battery management unit 12 is described.

The battery management unit 12 includes: a module control unit 12a, which controls overall operation of the device; a voltage detection circuit 12b; a temperature detection circuit 12c; an input/output unit 12d; a memory 12e; and a power supply circuit 12f.

The voltage detection circuit 12b detects the voltage of each of the plurality of battery cells 11a included in the secondary battery module 11 in a predetermined sampling cycle, and outputs information indicating the detected voltage, to the module control unit 12a. When the battery characteristics of the secondary battery module 11 are to be calculated, the voltage detection circuit 12b may detect the voltage between both ends of the secondary battery module 11. The sampling cycle is 10 milliseconds, for example, but is not limited thereto.

The temperature detection circuit 12c outputs, to the module control unit 12a, the surface temperature of one or a plurality of the plurality of battery cells 11a forming the secondary battery module 11. The temperature detection circuit 12c uses a temperature sensor 120c implemented as a thermistor, for example, and reads the temperature on the basis of the signal level of an output signal from the temperature sensor 120c. One temperature sensor 120c may be provided for the secondary battery module 11, or one temperature sensor 120c may be provided for each battery cell 11a. Use of a thermistor is an example. A known temperature sensor may be used as the temperature sensor 120c. For example, the temperature may be detected by using a temperature-measuring resistor, a semiconductor temperature sensor, a thermocouple, or the like.

It should be noted that the battery monitoring device 3 may be configured to detect the temperature by using a temperature sensor provided to one or a plurality of the plurality of secondary battery modules 11, and output the detected temperature to the battery management unit 12.

The input/output unit 12d is an interface for transmitting/receiving various types of information to/from the battery monitoring device 3.

The memory 12e is a nonvolatile memory such as a flash memory. The memory 12e has stored, in a read-only region thereof, management unit identification information (BMU?ID) of the device to which the memory 12e belongs. The memory 12e has stored therein information generated through processing performed by the module control unit 12a.

The power supply circuit 12f is a circuit that converts power supplied from the secondary battery module 11 so as to have a voltage appropriate for drive of each component of the battery management unit 12, and feeds the resultant power to each component of the battery management unit 12.

The module control unit 12a is implemented as a microcomputer having a processor such as a CPU (Central Processing Unit), a ROM (Read Only Memory), a RAM (Random Access Memory), a time measuring unit, an input/output interface, etc., a dedicated LSI (Large-Scale Integration), an FPGA (Field-Programmable Gate Array), or the like. The voltage detection circuit 12b, the temperature detection circuit 12c, the input/output unit 12d, and the memory 12e are connected to the input/output interface of the module control unit 12a, whereby operation of the battery module device 1 is controlled. Details of operations and functions of the module control unit 12a will be described later.

As shown in FIG. 2, the battery monitoring device 3 includes a control unit 30, a current detection unit 31, an input/output unit 32, a memory 33, a communication unit 34, and a power supply unit 35.

The control unit 30 is implemented as a microcomputer having a processor such as a CPU, a ROM, a RAM, a time measuring unit, an input/output interface, etc., a dedicated LSI, an FPGA, or the like. The control unit 30 transmits/receives information to/from each battery management unit 12 via the input/output unit 32, and processes the information. Specifically, the control unit 30 acquires information such as battery characteristics of each of the plurality of battery cells 11 a from each battery management unit 12. The control unit 30 may acquire information such as battery characteristics of each secondary battery module 11 from the corresponding battery management unit 12.

The current detection unit 31 is implemented as a shunt resistor, a Hall sensor, or the like for detecting the current of the secondary battery 10, for example, and detects a charge current or a discharge current of the secondary battery 10 in a predetermined sampling cycle. The sampling cycle is 10 milliseconds, for example, but is not limited thereto. The control unit 30 sequentially outputs a current value detected by the current detection unit 31 to each battery management unit 12 from the input/output unit 32. As shown in FIG. 2, the secondary battery 10 is formed by connecting the secondary battery modules 11 in series each obtained by connecting the battery cells 11a in series. Thus, when the current at an end of the secondary battery 10 is detected by one current detection unit 31, the current flowing in each battery cell 11 a and each secondary battery module 11 can be detected. It is understood that the battery management unit 12 may be configured to include a current detection unit 31 so as to detect a current.

The input/output unit 32 is connected to each of the plurality of battery management units 12. The input/output unit 32 is an input/output interface that allows the control unit 30 to transmit/receive information to/from the plurality of battery management units 12. The input/output unit 32 may be implemented as a wireless communication module, and the battery monitoring device 3 may wirelessly transmit/receive information to/from each battery management unit 12.

The memory 33 is a nonvolatile memory such as a flash memory. The memory 33 has stored therein management unit identification information (BMU?ID) of each of the plurality of battery management units 12 connected to the device to which the memory 33 belongs. The management unit identification information may be stored in advance as settings. Alternatively, the control unit 30 may input/output a signal with respect to each battery management unit 12, to collect the management unit identification information. The memory 33 may have stored therein, for each unit cell (secondary battery module 11 or battery cell 11a) of the secondary battery 10, unit cell identification information (MID: module ID, or CID: cell ID) that identifies the unit cell. The module ID is information that identifies a secondary battery module 11, and the cell ID is information that identifies a battery cell 11a.

The memory 33 has stored therein authentication key information for authenticating the battery monitoring device 3. The authentication key information is information of a secret key, for example.

The communication unit 34 is a communication module that realizes communication corresponding to an intra-vehicular communication network such as an intra-vehicular LAN (Local Area Network). The communication unit 34 can transmit/receive information to/from another in-vehicle device through CAN (Controller Area Network), for example. The communication unit 34 may be a wireless communication module that has a wireless communication antenna.

The communication unit 34 is connected to the TCU (Telematics Communication unit) 4. The TCU 4 performs communication with an external computer in accordance with a communication standard such as LTE (Long Term Evolution) or 3G, for example. Specifically, the TCU 4 performs communication with a node 21 forming the distributed-type database network 2.

The power supply unit 35 is a circuit that converts power from the secondary battery 10 so as to have a predetermined voltage value and that supplies the resultant power to each component.

In the battery monitoring device 3 having the above configuration, the control unit 30 comprehensively identifies the state of the secondary battery 10 on the basis of information obtained from the battery management unit 12 of each battery module device 1, thereby detecting an abnormality, and executes transmission/reception of information to/from another device.

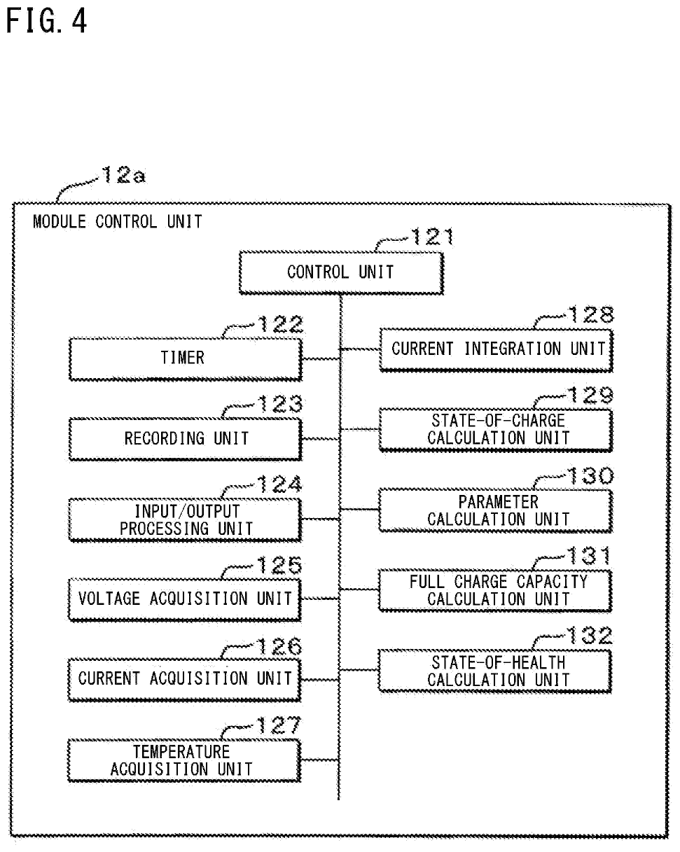

FIG. 4 is a function block diagram of the module control unit 12a in the embodiment. The module control unit 12a functions as: a control unit 121, which controls the entirety of the device; a timer 122; a recording unit 123; an input/output processing unit 124; a voltage acquisition unit 125; a current acquisition unit 126; a temperature acquisition unit 127; a current integration unit 128; a state-of-charge calculation unit 129; a parameter calculation unit 130; a full charge capacity calculation unit 131; and a state-of-health calculation unit 132.

The module control unit 12a, as the control unit 121, controls each component and calculates battery characteristics of each unit cell, which is the secondary battery module 11 or a battery cell 11a, on the basis of the voltage, temperature, and current that are detected. As the battery characteristics, the module control unit 12a calculates a full charge capacity (FCC), a state of charge (SOC), a state of health (SOH), and an equivalent circuit parameter, for example. The module control unit 12a functions as a battery characteristic calculation unit according to the present mode (1).

The module control unit 12a functions as the timer 122 by using a built-in time measuring unit. The timer 122 outputs a time measurement result to the control unit 121. In order to store the calculated battery characteristics in time series, the control unit 121 associates time information with the calculated battery characteristics, on the basis of the output from the timer 122.

The module control unit 12a functions as the recording unit 123 by using the memory 12e. The recording unit 123 temporarily records various types of information indicating battery characteristics calculated for each unit cell, which is the secondary battery module 11 or a battery cell 11a. The memory 12e has stored therein information for calculating the battery characteristics. For example, the memory 12e has stored therein information that is referred to in order to calculate a state of charge (SOC) for each unit cell. For example, the memory 12e has stored therein in advance correlation between open circuit voltage (OCV) and state of charge of the battery cell 11a.

The memory 12e has stored therein unit cell identification information (MID) of the secondary battery module 11 to be managed. The memory 12e may have stored therein unit cell identification information (CID) of each of the plurality of battery cells 11a forming the secondary battery module 11. Preferably, the unit cell identification information (MID or CID) is stored through processing performed by the recording unit 123 via a specific device or the battery monitoring device 3 by a work operator, when the secondary battery 10 including the secondary battery module 11 is mounted. A storage medium storing the unit cell identification information (MID or CID) may be mounted on the secondary battery module 11 or each battery cell 11a, and the unit cell identification information may be read out from the storage medium by the control unit 121, to be stored into the memory 12e.

The memory 12e has stored therein the initial (when the unit cell is new) full charge capacity or equivalent circuit parameter of each unit cell, as information for calculating the state of health of the unit cell. The initial full charge capacity or equivalent circuit parameter is preferably stored in, for example, the connection order of the unit cells so as to be able to be separately read out. The memory 12e may have stored therein, as information for calculating the state of health of each unit cell, relationship between increase rate of internal resistance and discharge capacity ratio corresponding to the state of health. These pieces of information when the unit cell is new may be stored through work by the above-described work operator.

The module control unit 12a controls, as the input/output processing unit 124, transmission/reception of information to/from the battery monitoring device 3 via the input/output unit 12d. The input/output processing unit 124 can transmit/receive information (FCC, SOC, SOH, or equivalent circuit parameter) indicating a battery characteristic of each unit cell to/from the battery monitoring device 3.

The module control unit 12a functions as the voltage acquisition unit 125, the current acquisition unit 126, and the temperature acquisition unit 127 which respectively acquire a voltage, a temperature, and a current to be used in calculation of the battery characteristics.

The voltage acquisition unit 125 acquires information indicating the voltage between both ends of the secondary battery module 11 or the voltage of each battery cell 11a outputted from the voltage detection circuit 12b. The voltage acquisition unit 125 may acquire the voltage between both ends of the secondary battery module 11 and the voltage at each battery cell 11a in a mutually-distinct manner.

The current acquisition unit 126 acquires, as a current value of the unit cell, information that indicates the current flowing in the secondary battery module 11 or the battery cell 11a that is obtained from the battery monitoring device 3 via the input/output unit 12d.

The temperature acquisition unit 127 acquires information indicating the temperature outputted from the temperature detection circuit 12c.

The module control unit 12a integrates, as the current integration unit 128, the current value acquired by the current acquisition unit 126. The integrated value of the current is obtained by integrating the current over time, and corresponds to the amount of change in the charge amount. The integrated value of the current is positive in the case of charge, and is negative in the case of discharge. An integrated value in a certain period can be positive or negative in accordance with the magnitude of the values of the charge current and the discharge current in the period. The timing to start integration calculation is the activation timing of the secondary battery 10, or the battery module device 1 or the battery monitoring device 3. The integrated value is continuously calculated. The integrated value may be reset at a predetermined timing, for example, in the case of reuse, at a timing when secondary battery modules 11 are recombined.

The module control unit 12a calculates, as the state-of-charge calculation unit 129, a state of charge of each unit cell, which is the secondary battery module 11 or a battery cell 11a. The state-of-charge calculation unit 129 obtains an open circuit voltage in the unit cell, which is the secondary battery module 11 or a battery cell 11a, and calculates, as estimation, a state of charge, by checking the open circuit voltage on the basis of correlation, between open circuit voltage and state of charge, that is stored in the recording unit 123. With reference to a state of charge at a specific time point, a state of charge may be calculated by using the charge current and the discharge current obtained through integration by the current integration unit 128, and a full charge capacity described later.

The module control unit 12a calculates, as the parameter calculation unit 130, a parameter of each element of an equivalent circuit corresponding to the unit cell. The parameters are resistance values Ra, Rb, a capacity Cb of a capacitor, and the like in the equivalent circuit.

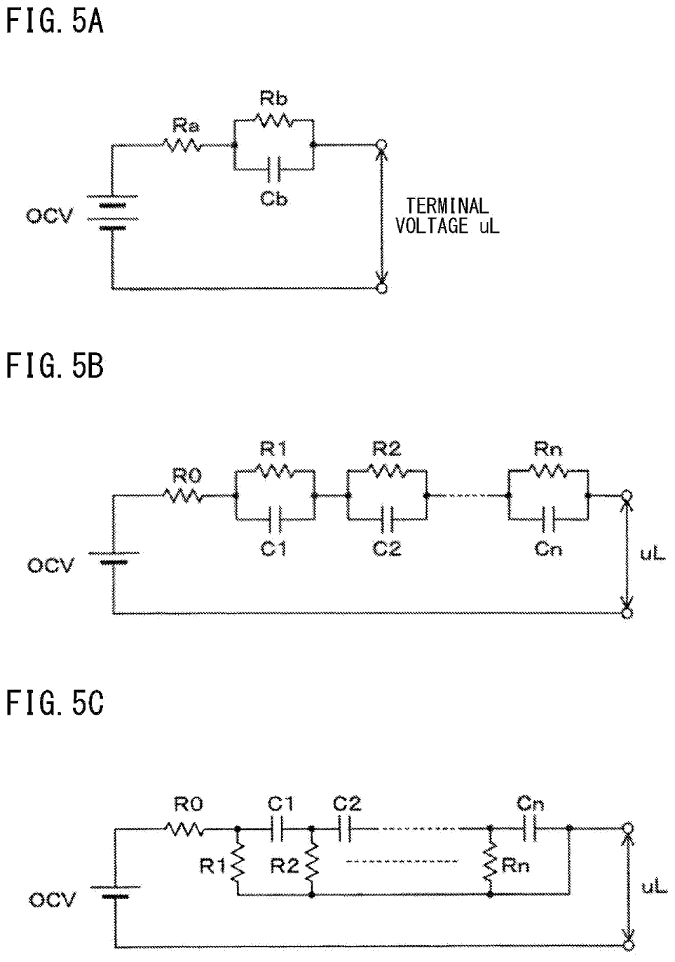

FIG. 5A, FIG. 5B, and FIG. 5C each illustrate an equivalent circuit model of a battery cell 11a. In the equivalent circuit model shown in FIG. 5A, the equivalent circuit is represented by a circuit in which a resistance Ra, and a parallel circuit of a resistance Rb and a capacitor Cb are connected in series to a voltage source having the open circuit voltage as an electromotive force. The resistance Ra corresponds to electrolyte resistance. The resistance Rb corresponds to charge transfer resistance. The capacitor Cb corresponds to electric double layer capacitance. The resistance Ra may include charge transfer resistance, and the resistance Rb may correspond to diffusion resistance.

The equivalent circuit of the unit cell is not limited to that shown in FIG. 5A. For example, as shown in FIG. 5B, the equivalent circuit may be an n-th order (n is a natural number) Foster-type RC ladder circuit represented by approximation with the sum of infinite series, in which n parallel circuits of a resistor Rj and a capacitor Cj (j=1, 2, . . . , n) are connected in series to a resistor R0. Alternatively, as shown in FIG. 5C, the equivalent circuit may be an n-th order Cowell-type RC ladder circuit in which ends of n resistors Rj (j=1, 2, . . . , n) are connected to each other and the other ends of the n resistors Rj are connected between n capacitors Cj connected in series.

The internal parameters of the equivalent circuit models shown in FIG. 5A, FIG. 5B, and FIG. 5C can be obtained by estimating, by a least squares method, parameters in approximate equations using a voltage value and a current value, for example. As the parameter estimation method, a known method may be used (for example, see “Battery Management System Engineering”, Shuichi Adachi et al., Tokyo Denki University Press, Chapter 6.2.2).

The internal parameters Ra, Rb, Cb may be calculated by using a Kalman filter. Specifically, the parameter calculation unit 130 compares an observation vector obtained when an input signal represented by a terminal voltage and a current is given to the unit cell and a state vector obtained when the same input signal is given to the equivalent circuit model of the unit cell. As a result of the comparison, the parameter calculation unit 130 multiplies the error between these vectors by the Kalman gain, and feeds back the result to the equivalent circuit model, thereby repeating correction of the equivalent circuit model such that the error between these vectors is minimized. The parameter calculation unit 130 can also estimate the internal parameters in this manner.

With reference back to FIG. 4, description of the functions of the module control unit 12a is continued. The module control unit 12a calculates, as the full charge capacity calculation unit 131, a full charge capacity per cell for each battery cell 11a. Various methods can be adopted as a full charge capacity calculation method performed by the full charge capacity calculation unit 131. For example, the full charge capacity calculation unit 131 checks a first open circuit voltage of the battery cell 11a at a first time point against the stored correlation, and calculates a first state of charge by means of the state-of-charge calculation unit 129. The first time point is a time point at which the starting switch is in an OFF state in a first trip period from the turn-on time point of the starting switch of the vehicle V to the next turn-on time point thereof. The full charge capacity calculation unit 131 calculates a second state of charge by means of the state-of-charge calculation unit 129 on the basis of a second open circuit voltage at a second time point. The second time point is a time point at which the starting switch is in an OFF state in a second trip period. The full charge capacity calculation unit 131 calculates, by means of the current integration unit 128, a charge/discharge amount on the basis of a charge/discharge current acquired by the current acquisition unit 126 in a period from the first time point to the second time point. The full charge capacity calculation unit 131 calculates a full charge capacity per cell of each battery cell 11a, on the basis of the first state of charge, the second state of charge, and the charge/discharge amount that have been calculated. The full charge capacity calculation unit 131 can also calculate a full charge capacity of the secondary battery module 11 as a unit, on the basis of the full charge capacity of each battery cell 11a. As the full charge capacity calculation method, another known method or a new method may be used.

The module control unit 12a calculates, as the state-of-health (SOH) calculation unit 132, a state of health of each unit cell, which is the secondary battery module 11 or a battery cell 11a. For example, the state-of-health calculation unit 132 calculates a state of health, by comparing the full charge capacity of the unit cell calculated by the full charge capacity calculation unit 131 against the initial full charge capacity stored in the recording unit 123. The state-of-health calculation unit 132 may calculate a proportion (degree of increase) of an internal resistance value R, against an initial value R0, calculated by the parameter calculation unit 130 with respect to the secondary battery 10 and may calculate a state of health on the basis of correlation between internal resistance increase rate and discharge capacity ratio stored in the recording unit 123. Further, the state-of-health calculation unit 132 may calculate a state of health by comparing the initial value of the equivalent circuit parameter stored in the recording unit 123 with a value calculated by the parameter calculation unit 130.

As the state-of-charge calculation unit 129, the parameter calculation unit 130, the full charge capacity calculation unit 131, and the state-of-health calculation unit 132 described above, various methods can be used for calculation of the battery characteristics. For example, methods disclosed in Japanese Laid-Open Patent Publication No. 2018-013456, Japanese Laid-Open Patent Publication No. 2017-203659, Japanese Laid-Open Patent Publication No. 2017-194284, Japanese Laid-Open Patent Publication No. 2017-194283, and the like, may be used.

The module control unit 12a calculates, as the control unit 121, all or part of the battery characteristics such as the state of charge, the equivalent circuit parameter, the full charge capacity, and the state of health in a predetermined cycle such as, for example, 10 milliseconds, temporarily stores the calculated battery characteristics, and performs charge/discharge control in accordance with the battery characteristics.

The control unit 121 outputs the battery characteristics of the secondary battery module 11 or each battery cell 11a to the battery monitoring device 3. The battery monitoring device 3 calculates the battery characteristics of the entirety of the secondary battery 10, and provides information for charge/discharge control as a whole, or for travel control and the like to another in-vehicle device.

The control unit 121 outputs, to the battery monitoring device 3, information used in calculation of the battery characteristics of the secondary battery module 11 or each battery cell 11a, e.g., the voltage value, the current value, and the temperature that have been detected, and information such as a calculation time at which the calculation of the battery characteristics has been performed.

The battery monitoring device 3 acquires, from each of the plurality of battery management units 12, the battery characteristics of the secondary battery module 11 or each battery cell 11a, the information used in calculation of the battery characteristics, and the calculation time. Then, via the TCU 4 to a specific node 21 forming the distributed-type database network 2, the battery monitoring device 3 transmits value information that includes a module ID, a cell ID, management unit identification information, calculation time, and battery characteristics, and monitoring device identification information. The monitoring device identification information is information for identifying the battery monitoring device 3 as the transmission source.

In addition, the battery monitoring device 3 transmits, to a specific node 21, detailed information serving as the calculation source of the battery characteristics of the secondary battery module 11 or each battery cell 11a.

The detailed information is information such as the voltage between both ends, the current, and the temperature of the secondary battery module 11 or each battery cell 11a, for example. The detailed information is sampled in a cycle of 0.1 seconds, for example. The detailed information may be transmitted in the sampling cycle, or a certain amount of detailed information may be accumulated and transmitted to the node 21.

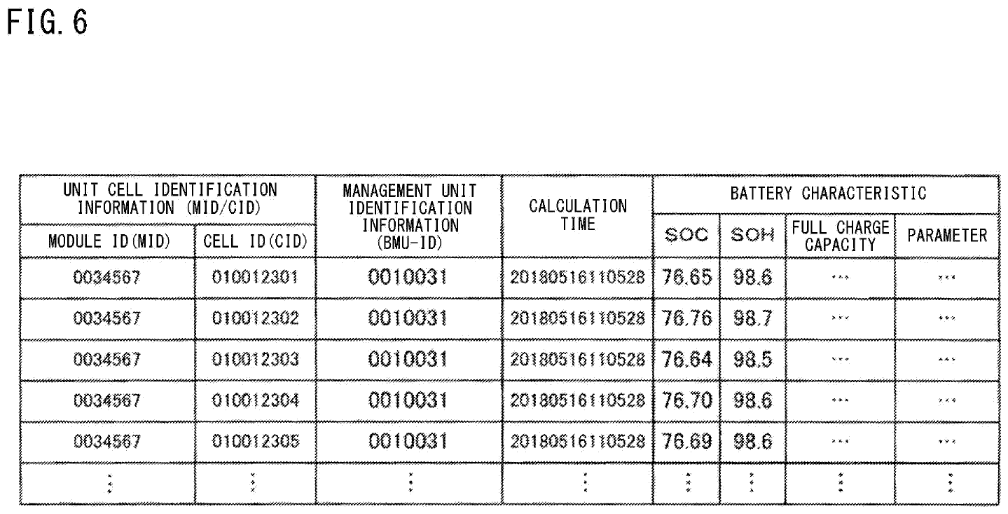

FIG. 6 is a conceptual diagram showing value information that is recorded into the distributed-type database network 2. The value information includes: a module ID and a cell ID which are the unit cell identification information (MID or CID); management unit identification information (BMU?ID); calculation time at which calculation of battery characteristics was performed; and battery characteristics such as FCC, SOC, SOH, or equivalent circuit parameter.

The value information also includes information for identifying the detailed information serving as the calculation source of the value information. Further, the value information includes confirmation information for confirming whether or not certain detailed information is consistent with detailed information that has been used in calculation of the battery characteristics included in the value information. As the confirmation information, parity information of the detailed information used in calculation of the battery characteristics may be used, for example.

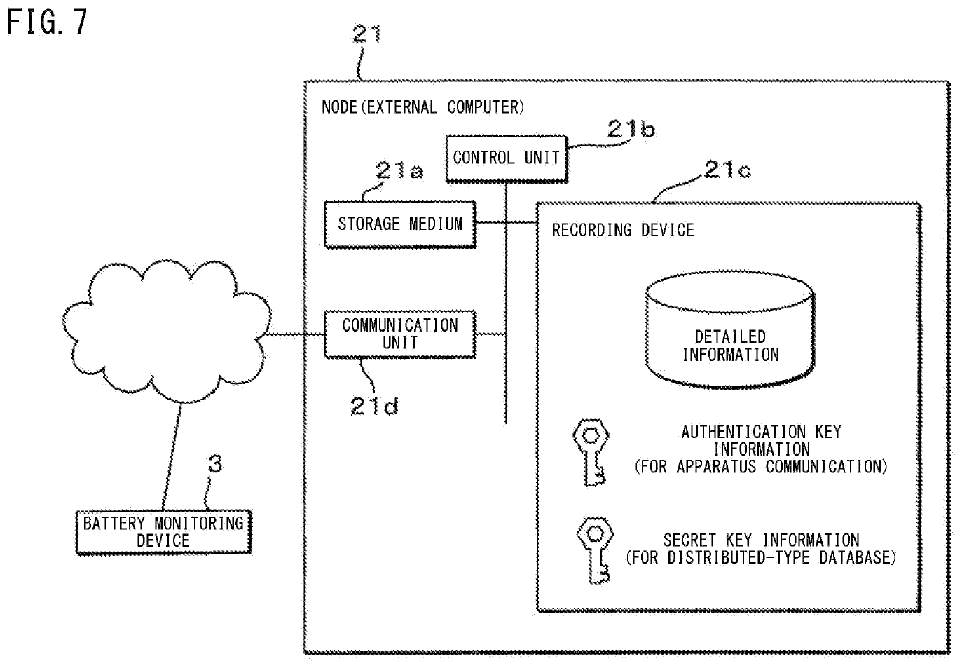

FIG. 7 is a block diagram showing a configuration example of a node 21. The node 21 is an external computer that is provided outside the apparatus on which the secondary battery module 11 is mounted. In particular, among the plurality of nodes 21 forming the distributed-type database network 2, the specific node 21 functions as an external computer that manages battery characteristics of each secondary battery module 11 or each battery cell 11a, and has authority of recording, into the distributed-type database network 2, value information or the like of the secondary battery module 11 or the battery cell 11a. The plurality of nodes 21 forming the distributed-type database network 2 each have the same configuration. Thus, here, the specific node 21 that performs management of the secondary battery module 11 or the battery cell 11a is described, and description of the other nodes 21 is omitted.

The node 21 includes a control unit 21b, a storage medium 21a, a recording device 21c, and a communication unit 21d. The control unit 21b is a computer that has a processor such as a CPU (Central Processing Unit) or a multi-core CPU, a ROM, a RAM, and the like. The communication unit 21d is a communication device that performs communication with the battery monitoring device 3, and receives detailed information and value information of the secondary battery module 11 or the battery cell 11a that are transmitted from the battery monitoring device 3. The communication unit 21d is connected to other nodes 21 forming the distributed-type database network 2, and transmits/receives information to/from each node 21.

The recording device 21c is a nonvolatile memory such as a hard disk or an EEPROM. The recording device 21c records detailed information transmitted from the battery monitoring device 3. The detailed information may be recorded into a relational database or the like. The recording device 21c has stored therein authentication key information for performing authentication of the battery monitoring device 3 and verification of information that is transmitted/received. The authentication key information is public key information obtained from secret key information of the battery monitoring device 3, for example.

Meanwhile, in the course of distribution of a secondary battery module 11 or a battery cell 11a including reuse thereof, the manager of the secondary battery module 11 or the battery cell 11a is changed, and the battery monitoring device 3 is also changed. Therefore, authentication key information of each of the plurality of battery monitoring devices 3 forming the battery information processing system according to the present embodiment is stored in the distributed-type database network 2 or the authority management node 22 so as to be unitarily managed, as described later. The node 21 acquires authentication key information of the battery monitoring device 3 from the distributed-type database network 2 or the authority management node 22, and the acquired authentication key information is stored into the recording device 21c.

In addition, the recording device 21c has stored therein secret key information for the distributed-type database network 2, and a public key and an address that are obtained on the basis of the secret key information.

FIG. 7 shows an example in which the storage medium 21a forming the distributed-type database network 2 and the recording device 21c having stored therein the detailed information of the secondary battery modules 11 and the battery cells 11a are separately provided. However, the storage medium 21a and the recording device 21c may be implemented by the same hardware.

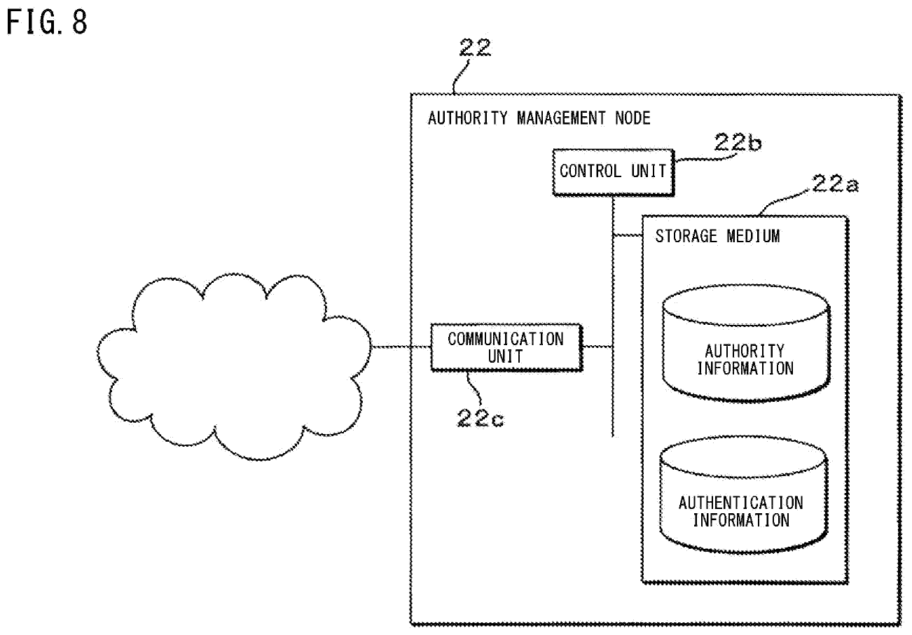

FIG. 8 is a block diagram showing a configuration example of the authority management node 22. The authority management node 22 includes a control unit 22b, a storage medium 22a, and a communication unit 22c. The control unit 22b is a computer that has a processor such as a CPU or a multi-core CPU, a ROM, a RAM, and the like. The communication unit 22c is connected to other nodes 21 forming the distributed-type database network 2, and transmits/receives information to/from each node 21.

The storage medium 22a has stored therein authority information that defines authority of a user who uses the distributed-type database network 2, in association with the ID of the user, the public key of the user, and the like. The authority information defines a range of value information that can be viewed by a user.

For example, there are authority that allows viewing of only the value information recorded by an immediately preceding manager, authority that allows viewing of the value information recorded by an immediately preceding manager and a manager before the immediately preceding manager, authority that allows viewing of the value information recorded by all of the managers, and the like.

Alternatively, the authority information may define the contents of battery characteristics that can be viewed.

The storage medium 22a stores therein authentication information for authenticating an apparatus, i.e., the battery monitoring device 3, that manages the state of each secondary battery module 11 or each battery cell 11a, and that transmits detailed information and value information of the secondary battery module 11 or the battery cell 11a, to the node 21. In the authentication information, monitoring device identification information for identifying each of a plurality of battery monitoring devices 3 and authentication key information for authenticating the battery monitoring device 3 are stored in association with each other. The battery monitoring device 3 that corresponds to the monitoring device identification information has stored therein unique secret key information. The storage medium 22a has stored therein, as the authentication key information, public key information that corresponds to the secret key information.

In the present embodiment, an example in which the authentication information of each battery monitoring device 3 is stored in the storage medium 22a of the authority management node 22 has been described. However, the storage medium 22a of another node 21 may unitarily manage the authentication information, or the authentication information may be recorded in a block chain.

A recording method of the detailed information and the value information of each battery cell 11a is described.

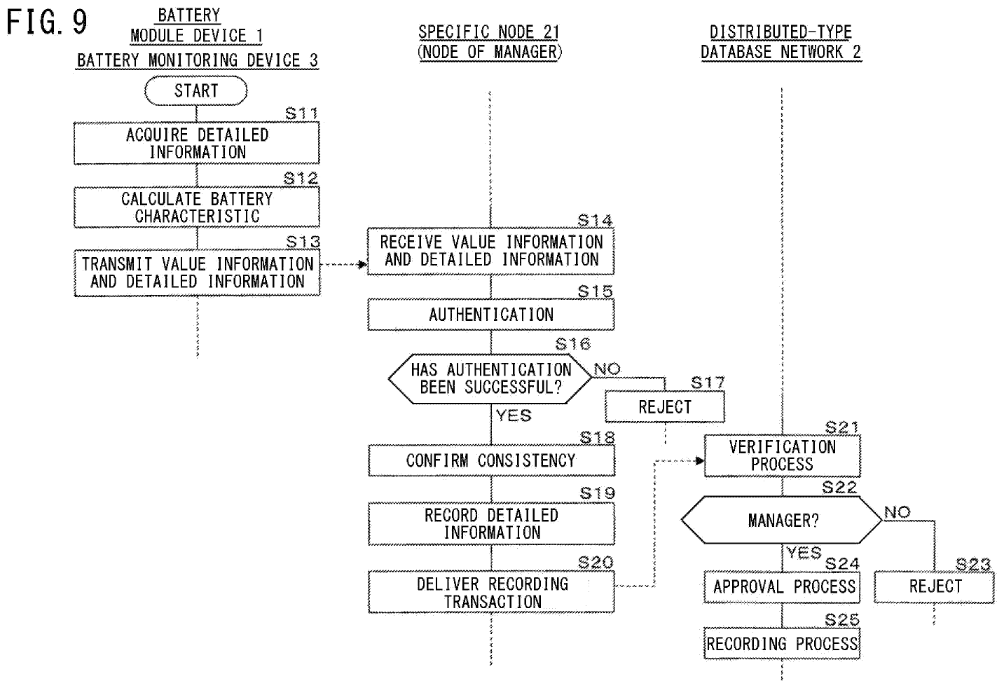

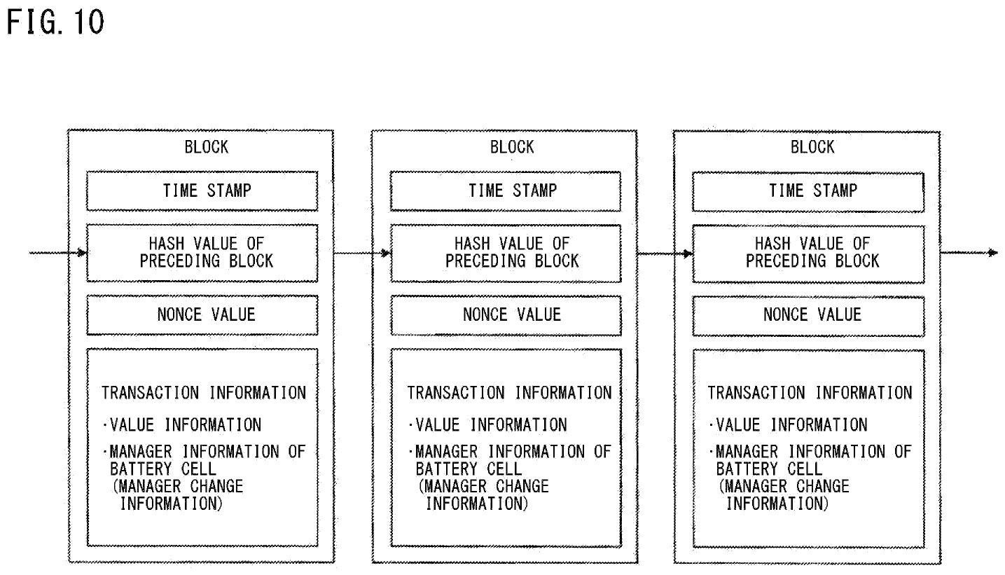

FIG. 9 is a flow chart showing a process procedure of recording value information and detailed information. FIG. 10 is a conceptual diagram of a block chain. The battery monitoring device 3 acquires detailed information outputted from each battery management unit 12 (step S11). The battery management unit 12 calculates battery characteristics of each of the plurality of battery cells 11a on the basis of the detailed information (step S12). Information of the calculated battery characteristics is outputted to the battery monitoring device 3.

The battery monitoring device 3 transmits, to a specific node 21 via the TCU 4, value information of the secondary battery module 11 or each battery cell 11a forming the secondary battery 10, and detailed information serving as the calculation source of the value information (step S13). An electronic signature generated by an authentication key is provided to the value information and the detailed information. The transmission destination of the value information and the detailed information is the node 21 of the manager who manages the secondary battery module 11 and the battery cell 11a. For example, the transmission destination is a node 21 owned and managed by the manager.

It should be noted that the control unit 30, the communication unit 34, and the like of the battery monitoring device 3 that execute the process of step S13 function as a transmission unit according to the present mode (1).

The specific node 21 managing the secondary battery module 11 and the battery cell 11a receives, by means of the communication unit 21d, the value information and the detailed information transmitted from the battery monitoring device 3 (step S14). The control unit 21b and the communication unit 21d of the node 21 that executes the process of step S14 form a reception unit according to the present mode (1). The node 21 performs authentication on the transmission source of the received value information and detailed information, by using authentication key information for apparatus communication (step S15), and determines whether or not the authentication has been successful (step S16). When having determined that the authentication has failed (step S16: NO), the node 21 rejects a recording process of the value information and the detailed information (step S17), and ends the process.

When having determined that the authentication has been successful (step S16: YES), the node 21 confirms consistency of contents between the value information and the detailed information that have been received (step S18). The value information includes information for identifying the detailed information serving as the calculation source of the value information, and the node 21 can identify the detailed information serving as the calculation source, by using the information. In addition, the value information includes confirmation information such as parity, and the node 21 can confirm consistency of contents between the value information and the detailed information, by using the confirmation information. The confirmation method of the consistency above is an example. As long as whether or not the detailed information is authentic detailed information that serves as the calculation source of the value information can be confirmed, another known technique may be used. The node 21 having ended the confirmation of consistency records the detailed information into the recording device 21c (step S19).

Next, the node 21 delivers a transaction of recording value data of the battery cell 11a, to the distributed-type database network 2 (step S20). An electronic signature based on secret key information of the node 21 is provided to the value information that is transmitted as the transaction. The control unit 21b, the communication unit 21d, and the like of the node 21 that execute the process of step S20 function as a transaction delivery unit according to the present mode (1).

An arbitrary node 21 forming the distributed-type database network 2 verifies the transaction delivered from the specific node 21 (step S21). The node 21 verifies whether the value information is authentic, on the basis of the electronic signature provided to the value information included in the transaction. The node 21 or the control unit 21b, of the distributed-type database network 2, that executes the process of step S21 functions as a verification processing unit according to the present mode (1).

The node 21 confirms whether or not the transmission source of the value information that is to be recorded and that has been authenticated in step S15 is the manager of the battery cell 11a according to the value information (step S22). Information that indicates the manager of the secondary battery module 11 and the battery cell 11a is recorded in the distributed-type database network 2. In step S22, the node 21 confirms whether or not the manager of the secondary battery module 11 or the battery cell 11a recorded in the distributed-type database network 2 is identical to the manager that corresponds to the transmission source node 21 of the value information.

When having determined that the transmission source of the value information is not the manager of the secondary battery module 11 or the battery cell 1 la (step S22: NO), the node 21 rejects recording of the value information (step S23). When having determined that the transmission source of the value information is the node 21 of the manager of the secondary battery module 11 or the battery cell 11a (step S22: YES), the node 21 performs an approval process of the block (step S24), and records the value information of the battery cell 11a into the distributed-type database network 2 (step S25).

The node 21 or the control unit 21b, of the distributed-type database network 2, that executes the process of step S24 functions as an approval processing unit according to the present mode (1). The node 21 or the control unit 21b, of the distributed-type database network 2, that executes the process of step S25 functions as a recording processing unit according to the present mode (1).

The block recorded into the distributed-type database network 2 includes a time stamp, a hash value of the preceding block, a nonce value, and transaction information. The nonce value is a value that realizes 0 in predetermined high-order bits of a hash value obtained from data of a block that is to be newly connected. The above approval process includes a process of calculating a nonce value. A block includes value information of the secondary battery module 11 or the battery cell 11a. The block also includes manager information indicating the manager of the secondary battery module 11 or the battery cell 11a, or manager change information indicating change of the manager. The manager change information is information that indicates the manager before the change and information that indicates the manager after the change.

A process procedure of changing the manager of the secondary battery module 11 is described.

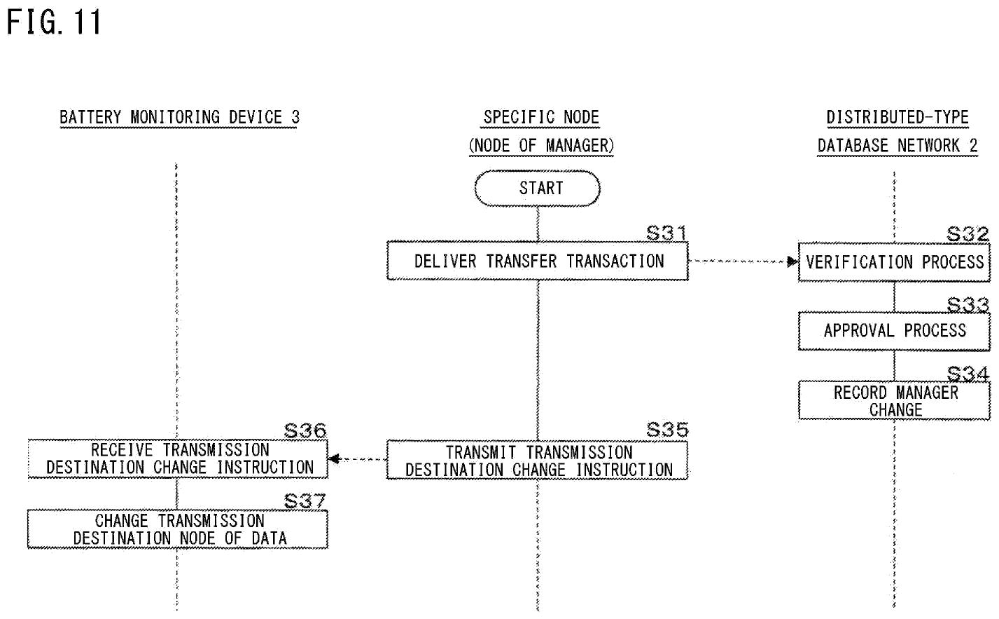

FIG. 11 is a flow chart showing a process procedure of changing the manager. For example, the specific node 21 delivers, to the distributed-type database network 2, a transaction of recording the change of the manager of the secondary battery module 11 and the battery cell 11a (step S31).

An arbitrary node 21 forming the distributed-type database network 2 executes a verification process on the transaction delivered from the specific node 21 above (step S32), and then, executes an approval process (step S33). When the verification process and the approval process have been completed without any problem, the node 21 records the information regarding the change of the manager, into the distributed-type database network 2 (step S34).

Meanwhile, the node 21 transmits change instruction information that instructs change of the transmission destination of value information and detailed information, to the transmission source battery monitoring device 3 (step S35). The instruction information includes the transmission destination address indicating a node 21 to which value information and detailed information should be transmitted after the change of the manager. The transmission destination address for transmitting information to a node 21 forming the battery information processing system, in particular, a node 21 that performs reception and a recording process of value information and detailed information is recorded in the distributed-type database network 2 or the authority management node 22, for example. The node 21 only needs to acquire a new transmission destination address after the manager change, from the distributed-type database network 2 or the authority management node 22.

The battery monitoring device 3 receives the change instruction information (step S36). Then, the battery monitoring device 3 changes the transmission destination of value information and detailed information (step S37). Thereafter, the battery monitoring device 3 transmits value information and detailed information to the node 21 of the new manager.

A viewing method of value information and detailed information is described.

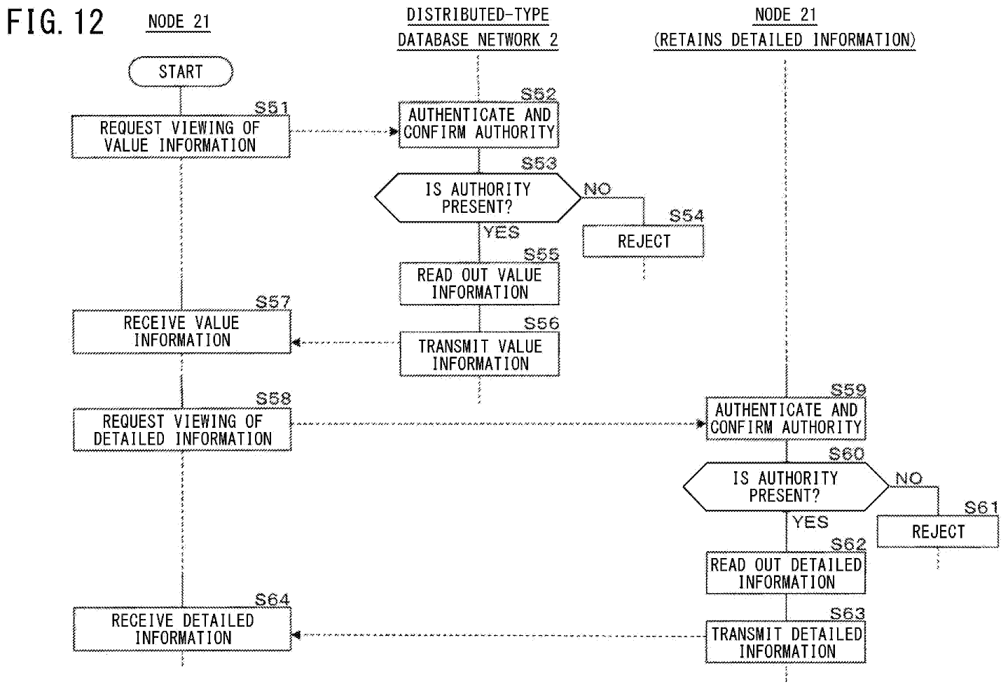

FIG. 12 is a flow chart showing a process procedure of viewing value information and detailed information. An arbitrary node 21 requests viewing of value information of a secondary battery module 11 or a battery cell 11a (step S51). The viewing request includes information such as the module ID of the target secondary battery module 11 or the cell ID of the target battery cell 11a, a period of the target viewing (calculation time of battery characteristics), and the like. The distributed-type database network 2 authenticates the viewing-request-source node 21, and confirms authority (step S52). The distributed-type database network 2 refers to authority information recorded in the storage medium 22a of the authority management node 22, and confirms authority of the viewing request source.

The distributed-type database network 2 determines whether or not viewing authority is present (step S53). When having determined that the viewing authority is absent (step S53: NO), the distributed-type database network 2 rejects the viewing request (step S54). When having determined that the viewing authority is present (step S53: YES), the distributed-type database network 2 reads out, from the distributed-type database network 2, value information for which the viewing request has been issued (step S55), and transmits the read out value information to the request-source node 21 (step S56).

The node 21 receives the value information transmitted from the distributed-type database network 2 (step S57). The node 21 displays the received value information, or outputs the received value information by a method of, for example, transmitting to a user terminal.

Next, the node 21 requests viewing of detailed information as necessary (step S58). The viewing request of detailed information is performed to a node 21 that has delivered a transaction related to calculation or recording of the value information, for example.

The node 21 authenticates the viewing-request-source node 21, and confirms authority (step S59). For the confirmation of the authority, viewing authority of value information that corresponds to the detailed information may be confirmed by making an inquiry to the authority management node 22, for example.

The viewing-request-destination node 21 determines whether or not viewing authority is present (step S60). When having determined that the viewing authority is absent (step S60: NO), the node 21 rejects the viewing request (step S61). When having determined that the viewing authority is present (step S60: YES), the viewing-request-destination node 21 reads out, from the recording device 21c, detailed information for which the viewing request has been issued (step S62), and transmits the read out detailed information to the request-source node 21 (step S63).

The viewing-request-source node 21 receives the detailed information (step S64). The node 21 displays the received detailed information or outputs the received detailed information by a method of, for example, transmitting to a user terminal.

In the above description with reference to FIG. 12, an example in which value information and detailed information of secondary battery modules 11 or battery cells 11a are transmitted as they are to the viewing-request-source user has been described. However, information obtained by processing these pieces of information may be transmitted to the transmission source. For example, on the basis of value information and detailed information of secondary battery modules 11 or battery cells 11a, the deterioration states of the secondary battery modules 11 or the battery cells 11a are ranked, and ranking information may be transmitted to the information request source.

According to the battery state management system having such a configuration, during use of an apparatus on which a secondary battery module 11 is mounted, battery characteristics of the secondary battery module 11 can be recorded per module or per battery cell 11a in such a manner as not to be falsified, whereby battery characteristics of each battery cell 11a can be read out when necessary.

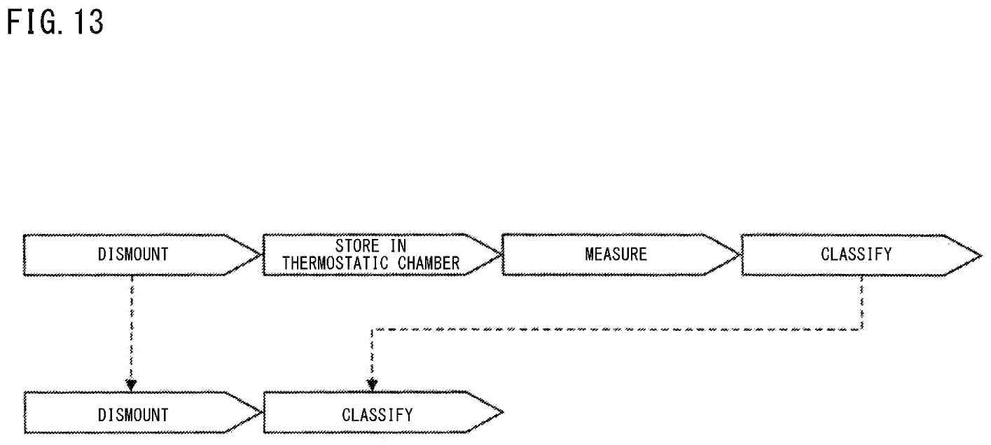

FIG. 13 is a conceptual diagram for describing effects of the battery information management system according to the present embodiment. In a case where a secondary battery module 11 and a battery cell 11a are to be reused, conventionally, as shown in the upper part of FIG. 13, it is necessary to: dismount the secondary battery module 11 from the vehicle V; store the secondary battery module 11 in a thermostatic chamber; perform various measurements by causing the secondary battery module 11 or the battery cell 11a to be charged/discharged; calculate battery characteristics; and classify the secondary battery module 11 or the battery cell 11a in accordance with the deterioration state.

According to the present embodiment, by viewing the value information of the secondary battery module 11 or the battery cell 11a recorded in the distributed-type database network 2, it is possible to immediately select the secondary battery module 11 or the battery cell 11a in accordance with the deterioration state. Therefore, reuse of the secondary battery module 11 and the battery cell 11a can be efficiently performed.

In the present embodiment, manager information and manager change information that indicate the manager of the secondary battery module 11 and the battery cell 11a are recorded in the distributed-type database network 2. Therefore, authenticity of information regarding the manager who has calculated and recorded the value information of the battery cell 11a is ensured. Therefore, traceability of the secondary battery module 11 and the battery cell 11a with respect to the value information can be improved.

In the present embodiment, the transaction of recording the value information is recorded into the distributed-type database network 2 only when the transaction has been delivered from a specific node 21 that corresponds to the manager of the secondary battery module 11 and the battery cell 11a. A transaction that has been delivered from a node 21 other than that of the manager of the secondary battery module 11 and the battery cell 11a is not recorded into the distributed-type database network 2 even when the transaction itself is authentic. Therefore, authenticity of the value information can be improved. Accordingly, traceability of the secondary battery module 11 and the battery cell 11a with respect to the value information can be improved.

In the present embodiment, the range of the value information that can be viewed can be restricted in accordance with the authority of the user.

In the present embodiment, value information of the secondary battery module 11 and the battery cell 11a is recorded into the distributed-type database network 2, and detailed information having a large volume can be recorded into the recording device 21c. Since both of the value information and the detailed information of the secondary battery module 11 and the battery cell 11a are recorded, reliability of the value information can be more improved. Therefore, traceability of the secondary battery module 11 and the battery cell 11a with respect to the value information can be further improved.

In the present embodiment, the user who can read out value information from the distributed-type database network 2 can request, to a node 21, detailed information that corresponds to the value information, and acquire the detailed information. The user can confirm in more detail the state of the secondary battery module 11 and the battery cell 11a, on the basis of the value information and the detailed information.

It should be noted that the embodiment disclosed herein is merely illustrative and is not restrictive in all aspects. The scope of the present disclosure is defined by the scope of the claims rather than the embodiment described above, and is intended to include meaning equivalent to the scope of the claims and all modifications within the scope.

### REFERENCE SIGNS LIST

1 battery module device

2 distributed-type database network

3 battery monitoring device

4 TCU

10 secondary battery

11 secondary battery module

11a battery cell

12 battery management unit

12a module control unit

12b voltage detection circuit

12c temperature detection circuit

12d input/output unit

12e memory

12f power supply circuit

21 node

21a storage medium

21b control unit

21c recording device

21d communication unit

22 authority management node

22a storage medium

22b control unit

22c communication unit

30 control unit

31 current detection unit

32 input/output unit

33 memory

34 communication unit

35 power supply unit

120c temperature sensor

121 control unit

122 timer

123 recording unit

124 input/output processing unit

125 voltage acquisition unit

126 current acquisition unit

127 temperature acquisition unit

128 current integration unit

129 state-of-charge calculation unit

130 parameter calculation unit

131 full charge capacity calculation unit

132 state-of-health calculation unit

V vehicle

1. A battery information management system configured to manage a reuse value of a secondary battery that includes a plurality of unit cells, the battery information management system comprising:
a battery characteristic calculation unit configured to calculate a battery characteristic for each of the plurality of unit cells;
a transmission unit configured to transmit value information that includes the battery characteristic, of each unit cell, calculated by the battery characteristic calculation unit, unit cell identification information identifying the unit cell, and time information indicating a time at which the battery characteristic has been calculated; and
a distributed-type database network configured to record the value information, of each unit cell, transmitted by the transmission unit, wherein
the distributed-type database network includes a plurality of nodes each having a storage medium,
a specific node of the plurality of nodes
is a computer configured to manage the battery characteristic of the unit cell, and
includes
a reception unit configured to receive the value information transmitted from the transmission unit, and
a transaction delivery unit configured to deliver, to the plurality of nodes, a transaction of recording the value information received by the reception unit, and
each of the plurality of nodes includes
a verification processing unit configured to perform verification on the value information relating to the transaction,
an approval processing unit configured to approve the value information that has been verified, and
a recording processing unit configured to record the value information that has been approved, into the storage medium.

2. The battery information management system according to claim 1, wherein
the distributed-type database network is configured to record manager information indicating a manager of the unit cell and information regarding change of the manager.

3. The battery information management system according to claim 2, wherein
when the transaction of recording the value information of the unit cell has been delivered from the specific node that corresponds to the manager of the unit cell, the distributed-type database network records the value information, and when the transaction has been delivered from a node that does not correspond to the manager, the distributed-type database network rejects recording of the value information.

4. The battery information management system according to claim 3, wherein
the distributed-type database network
provides viewing authority of the value information to a user of the distributed-type database network, and
manages a range of the value information that is allowed to be viewed by the user.

5. The battery information management system according to claim 1, wherein
the transmission unit is configured to transmit detailed information serving as a calculation source of the battery characteristic, and the reception unit is configured to receive the detailed information transmitted from the transmission unit, and
the specific node
includes a recording device outside the distributed-type database network, and
records, into the recording device, the detailed information received by the reception unit.

6. The battery information management system according to claim 4, wherein
the transmission unit is configured to transmit detailed information serving as a calculation source of the battery characteristic, and the reception unit is configured to receive the detailed information transmitted from the transmission unit, and
the specific node
includes a recording device outside the distributed-type database network, and
records, into the recording device, the detailed information received by the reception unit, and when having received a request from a user having viewing authority of the value information recorded in the distributed-type database network, transmits the detailed information recorded in the recording device, to a source of the request.

7. The battery information management system according to claim 1, wherein
when a manager of the unit cell has been changed, the transmission unit changes the specific node serving as a transmission destination of the value information.

8. A specific node being a computer configured to manage a battery characteristic of each of a plurality of unit cells forming a secondary battery,
the specific node comprising:
a reception unit configured to receive value information that includes the battery characteristic of each unit cell, unit cell identification information identifying the unit cell, and time information indicating a time at which the battery characteristic has been calculated;
an authentication unit configured to perform authentication on a transmission source of the value information; and
a transaction delivery unit configured to deliver, on the basis of an authentication result of the authentication unit, a transaction for recording the value information, to a plurality of nodes included in a distributed-type database network, wherein
each of the plurality of nodes includes a storage medium into which the value information of the unit cell is recorded.

9. A node forming a distributed-type database network including a plurality of nodes each having a storage medium, the node comprising:
a verification processing unit configured to perform verification on value information relating to a transaction that has been delivered from a specific node and that is for recording the value information into the distributed-type database network;
an approval processing unit configured to approve the value information that has been verified; and
a recording processing unit configured to record the value information that has been approved, into the storage medium, wherein
the value information includes a battery characteristic of each of a plurality of unit cells forming a secondary battery, unit cell identification information identifying each unit cell, and time information indicating a time at which the battery characteristic has been calculated.

10. A management method for a battery characteristic of each of a plurality of unit cells forming a secondary battery, the management method being configured to be performed by a computer configured to manage the battery characteristic, the management method comprising the steps of:
receiving value information that includes the battery characteristic of each unit cell, unit cell identification information identifying the unit cell, and time information indicating a time at which the battery characteristic has been calculated;
performing authentication on a transmission source of the value information; and
delivering, on the basis of an authentication result regarding the transmission source, a transaction for recording the value information, to a plurality of nodes included in a distributed-type database network, wherein
each of the plurality of nodes includes a storage medium into which the value information of the unit cell is recorded.

11. A recording method, of value information, performed by a node forming a distributed-type database network that includes a plurality of nodes each having a storage medium, the recording method comprising the steps of:
performing verification on value information relating to a transaction that has been delivered from a specific node and that is for recording the value information into the distributed-type database network;
approving the value information that has been verified; and
recording the value information that has been approved, into the storage medium, wherein
the value information includes a battery characteristic of each of a plurality of unit cells forming a secondary battery, unit cell identification information identifying each unit cell, and time information indicating a time at which the battery characteristic has been calculated.

12. (canceled)

13. (canceled)
